(19) United States
(12) Patent Application Publication
(10) Pub. No.: US 2015/0311673 A1
(43) Pub. Date: Oct. 29, 2015

(54) Polarization Control in High Peak Power, High Brightness VCSEL

(71) Applicant: Princeton Optronics Inc., Mercerville, NJ (US)

(72) Inventors: Qing Wang, Plainsboro, NJ (US); Jean-Francois Seurin, Princeton Junction, NJ (US); Chuni L Ghosh, West Windsor, NJ (US); Laurence S Watkins, Pennington, NJ (US)

(73) Assignee: Princeton Optronics Inc., Mercerville, NJ (US)

(21) Appl. No.: 14/700,010

(22) Filed: Apr. 29, 2015

Related U.S. Application Data
(60) Provisional application No. 61/985,776, filed on Apr. 29, 2014.

(51) Int. Cl. H01S 5/068; H01S 5/02; H01S 5/183; H01S 5/42; H01S 5/187; H01S 5/042

(52) U.S. Cl. CPC H01S 5/06821; H01S 5/187; H01S 5/0425; H01S 5/18361; H01S 5/423; H01S 5/0217

(57) ABSTRACT

A new VCSEL design is presented to achieve high output power and high brightness with a strong selection of a linear polarization state in high speed pulsing operation. Higher output power is achieved by including multiple gain segments in tandem, in the gain region. To achieve single mode operation with high output power, an extended cavity three reflector design is presented. High degree of polarization selectivity is achieved by a linear grating deployed with the third reflector, such that lasing is allowed only in a preferred linear polarization state. A polarization selective reflector including a linear grating is designed to impart strong polarization selectivity for a preferred linear polarization state. The polarization selective reflector used as the third reflector in an extended cavity VCSEL device, exhibits strong polarization selection for a preferred linear polarization state during high speed pulsing including in the gain switching resonance regime.

### CROSS REFERENCE TO RELATED APPLICATION

The present application seeks priority from the United States Provisional Patent Application No. 61/985,776 filed on Apr. 29, 2014, the content of which is being incorporated by reference in its entirety.

### BACKGROUND OF THE INVENTION

1. Field of the Invention

The present invention relates to high brightness VCSELs including single VCSEL and VCSEL arrays, and in particular to extended cavity VCSELs having high peak power and high brightness emission with linear polarization, suitable for high speed pulse operation.

2. Related Background Art

VCSELs have many beneficial properties over other lasers, especially edge emitting semiconductor lasers. They can generate round beams of radiation with good collimation for many different wavelengths. They are stable with varying operating temperature having very small changes in operating wavelength contributing significantly to long-term reliability. VCSELs are operable using very short pulses at high pulse rates with very fast pulse rise times resulting from gain switching, relaxation resonance properties. There are many emerging applications and in particular, applications in consumer electronics for example, in the areas of 3D imaging, gesture recognition, optical I/O, Active Optical Cables (AOC), high speed telecom and datacom applications, optical displays and interactive input devices, etc. that would benefit from the availability of high brightness, high speed VCSELs at a low cost.

Due to their surface emission design VCSELs are highly suitable for constructing one or two dimensional arrays of light sources that may be electrically connected to operate in parallel, in groups or in individually addressable mode. They are envisioned to be ideal for compact Opto-Electronic Integrated Circuits (OEIC) as has been described in the U.S. Pat. No. 4,999,842 issued on Mar. 12, 1991, to Huang et al, U.S. Pat. No. 5,206,872 issued on Apr. 27, 1993, to Jewell et al., and U.S. Pat. No. 4,991,179 issued on Feb. 5, 1991, to Deppe et al. However, in earlier devices, producing VCSELs and OEICs using VCSELs in large volume compatible with high volume production processes was a challenge because of several limitations pertaining to large area defect free wafer growth, defect and stress free growth of epitaxial layers that form the foundation structure of the VCSEL devices, and absence of compatible wafer processing methods to include different semiconductor material on a common compatible platform. Some of these challenges are met by hybrid integration combined with advanced techniques of wafer bonding.

A basic two mirror (reflector) VCSEL commonly known in the art comprises a gain region placed in a cavity formed between two reflectors. A basic VCSEL device operates typically in a single transverse mode with very low optical output power. In most common type of VCSEL device the gain region is comprised of a homogeneous material or a single/multiple quantum well structure confined typically between Distributed Bragg Reflectors (DBRs). A lot of research and development is devoted for over two decades to innovative designs both in the basic VCSEL device structure as well as to peripheral devices to improve heat dissipation capacity, parasitic circuit elements, etc. so that VCSEL delivers high output power and can be operated with higher drive current, shorter pulses (shorter rise and fall times) and/or at high pulse rate. While output power can be successfully increased by operating a basic two reflector VCSEL at higher drive current, brightness of the beam does not increase significantly because the power is channeled in several modes including fundamental and higher order modes.

Therefore, it is not only important to increase output power, it is more important to confine most of the optical power in a single optical mode, preferably in a low order fundamental mode. A lot of prior art VCSEL designs focused on addressing the current confinement within a small area (smaller compared to the cavity length or height in the context of a VCSEL) of the gain region preferably in the central part of the VCSEL. To achieve this goal an annular region of high resistivity is typically created around the central region of the VCSEL structure by selective oxidation, proton implantation or dielectric layer deposition. Many methods are well documented in many prior art patent and non-patent literature for example, European Patent Application publication No. EP 1276188 by Sopra published on Jan. 15, 2003, United States Patent Application publication No. 20020172247 by Sopra et al. published on Nov. 21, 2002, in the European Patent Application publication No. EP0905835 by Sun published on Mar. 31, 1999, in the United States Patent Application publication No. 20130034117 by Hibbs-Brenner et al. published on Feb. 7, 2013, and a research report published by Finisar Corporation in 2007, entitled “Reliability of Various Size Oxide Aperture VCSELs” just to mention a few.

There are many other methods described to limit optical power in a single mode. For example, European Patent Application publication No. EP1496583 by Royo published on Jan. 12, 2005, describes a method to construct the oxide aperture having a specific correlation between the mesa and oxide aperture diameters. In the U.S. Pat. No. 6,965,626 issued to Tatum et al. on Nov. 15, 2000, two self-aligned apertures are located in the upper and lower Distributed Bragg Reflectors (DBRs) to confine the electrical current in a very narrow lateral region of the vertical cavity for a desired mode selection. Current limiting apertures are also used to tailor the gain profile to improve mode selection as described in the PCT Patent Application publication No. WO2013014563 by Gronenborn et al. published on Jan. 31, 2013. Two oxide apertures located one on either side of the gain region is also described in the United States Patent Application publication No. 20070242716 by Samal et al. published on Oct. 18, 2007.

In a different approach additional features are included within the vertical cavity to confine laser emission in a single mode. For example, in the U.S. Pat. No. 6,061,381 issued to Adams et al. on May 9, 2000, a set of concentric rings are constructed in a current blocking region to provide a specific phase characteristics that supports a desired optical mode usually, but not necessarily the lowest order fundamental mode, over other optical modes. In another method, layers with special characteristics are grown within the epitaxial layer stack to select desired transverse mode. For example, in the United States Patent Application Publication No. 20040213311 published on Oct. 24, 2004, and U.S. Pat. No. 6,905,900 issued on Jun. 14, 2005, both by Johnson et al., an equipotential layer separated by an insulator layer is grown on the upper DBR to define an aperture to select the lowest order transverse mode while suppressing the higher order modes. In the U.S. Pat. No. 5,245,622 issued to Jewell et al. on Sep. 14, 1993, an aperture with a stratified electrode between the upper mirror and an upper spacer layer is employed to select a single optical mode.

Alternatively, lateral waveguides may be used to confine optical mode in the gain region of the vertical cavity that is described in the U.S. Pat. No. 5,337,327 issued on Aug. 9, 1994 to Ackley and U.S. Pat. No. 5,164,949 issued on Nov. 17, 1992 to Ackley et al. Somewhat similar effect is also achieved by radially grading resistivity in a pre-determined layer of the VCSEL cavity structure to restrict current flow in the radial direction to an area smaller than the cavity length as described in the U.S. Pat. No. 5,343,487 issued on Aug. 30, 1994, to Scott et al., and U.S. Pat. No. 5,594,751 issued on Jan. 14, 1997, to Scott, respectively. In U.S. Pat. No. 6,885,690 issued to Aggerstam et al., on Apr. 26, 2005, an additional dielectric mirror smaller in diameter than the upper DBR is positioned above the upper DBR for mode selection.

In a different approach, a wavelength dependent reflectivity is generated by employing a photonic crystal region embedded in or near the upper DBR such that only a single mode is supported. This is described in the U.S. Pat. No. 6,810,056 issued on Oct. 26, 2004, and U.S. Pat. No. 7,668,220 issued on Feb. 23, 2010, both to Lipson et al. In the U.S. Pat. No. 7,693,203 issued on Apr. 6, 2010, to Birkedal et al, photonic crystal is used to create regions that incur large losses for longitudinal modes. The photonic crystal characteristics are designed to support single fundamental mode operation.

However to restrict the power in a single mode the aperture(s) has to be smaller in diameter as compared to the lateral dimension of the VCSEL cavity, such that higher order modes are attenuated. In order to further increase the power in a single mode to increase brightness, the laser cavity parameters need to be increased to increase the mode diameter to draw power from a larger volume of the gain region. This may be achieved by expanding the cavity volume, and in particular the cavity length that facilitates increasing the mode diameter of the lasing mode(s). As a consequence, a larger aperture may be used to confine a single mode thereby expanding the volume of the gain region contributing to laser emission to obtain higher optical power in a single mode.

Further increase in output power may be achieved with extended cavity length (or height). In a variation from the basic VCSEL design where the mirrors defining the cavity is in immediate proximity of the gain region, the lower DBR may be located on the opposite side of the substrate such that the substrate is in between the active light generating region and the lower DBR. VCSELs incorporating this design idea are described in U.S. Pat. No. 7,620,088 issued on Nov. 17, 2009, to Stein et al., and U.S. Pat. No. 5,461,637 issued on Oct. 24, 1995, to Mooradian where the second reflector is deposited on a transparent substrate that is bonded to the VCSEL wafer. In a slightly different design described in the U.S. Pat. No. 6,026,111 issued on Feb. 15, 2000, to Jiang et al, an external mirror is provided by a specially designed dielectric reflective coating on a separate transparent substrate that is wafer bonded to the VCSEL structure such that higher order modes have high modal loss while supporting a single lower order mode.

Much higher output power in a single mode to achieve higher brightness may be accomplished in a Vertical Extended Cavity Surface Emitting Laser (VECSEL) using a third reflector (mirror) also known as coupled cavity laser. The concept although existed in other types of lasers, was recently used for VCSELs. One object of this design is to increase the resonant cavity length enabling operation in a low order mode at higher power. There are two options to configure a VECSEL—one which includes a third mirror external to the main VCSEL structure or, where the third mirror is integrated or bonded to the VCSEL structure but placed outside the VCSEL cavity, such that the lasing is set up between the mirrors that are at the extreme boundaries of cavity. In both the configurations the reflectivity of the intermediate mirror is set very low such that no lasing occurs between the mirrors at the boundaries of the cavity and the intermediate mirror.

VCSELs incorporating the design principles of coupled cavity lasers are described in the U.S. Pat. No. 6,778,582 issued on Aug. 17, 2004, and U.S. Pat. No. 6,898,225 issued on May 24, 2005, both to Mooradian, and U.S. Pat. No. 6,661,829 issued on Dec. 9, 2003, to Jeon, where a third mirror is placed externally to the VCSEL cavity to provide a stable transverse mode having high output power. More recently, innovations disclosed in U.S. Pat. No. 8,675,706 by Seurin et al. issued on Mar. 18, 2014, and in a pending U.S. patent application Ser. No. 13/337,098 filed on Dec. 24, 2011, both by Seurin et al., and U.S. patent application Ser. No. 14/634,902 filed on Mar. 4, 2015 by Wang et al., all applicants of this application as well, and co-owned by the Assignee of this application, Princeton Optronics Inc., Mercerville, N.J., has enabled VCSELs and VCSEL arrays of different designs including configurations having three reflectors either integrated or placed externally to the VCSEL device (including arrays), to be produced according to large volume processes on large area wafers (6″ diameter) in forms that are compatible for surface mounting with other electronic components, have paved the way to high density optical modules (OMs) and/or OEICs. Contents of these above mentioned patent publications co-authored by some of the inventors of this application and co-owned by Princeton Optronics Inc. Mercerville, N.J., and are being incorporated by reference in their entirety.

While the three mirror VCSEL designs mentioned earlier are relatively successful in achieving high output power, the output power and brightness (defined as high output power in a single mode) is limited by total volume of a single gain region or light emitting region in the gain cavity of a typical VCSEL device. Even higher output power together with higher brightness can be achieved by employing multiple light emitting regions or multiple gain segments in the gain cavity. In the U.S. Pat. No. 7,502,401 issued on May 10, 2009, to Miller et al. a VCSEL design having multiple integrated gain regions comprising a resonant periodic gain region is described. Multiple gain regions are configured as transverse p-n junctions at standing wave antinodes of a cavity defined by a top and a bottom mirror. In a different design described in the United States Patent Application publication No. 20130243024 by Hara, published on Sep. 19, 2013, a multiple gain region structure is described which can be optically or electrically pumped to configure as a VCSEL. Notably, the gain regions are located at the antinodes whereas current blocking layers are located at the nodes of the standing waves. Light emitting region having multiple gain segments is also described in the PCT Application publication No. WO2011013498 by Takeuchi published on Feb. 3, 2011, where adjacent gain regions are provided with different number of MQWs to achieve a desired gain profile in an optical mode.

In a variant design described in many different semiconductor material systems, multiple light emitting regions are separated by tunnel junctions to supply minority carriers in the gain region. Those skilled in the art may be able to appreciate that an n-layer in close contact with a p-layer of adjacent gain region in the VCSEL cavity may result in restrictive carrier flow in the gain region. A slightly reversed biased tunnel junction including a heavily doped p⁺⁺ and n⁺⁺ regions located adjacent to each other may be deployed between the adjacent gain regions to overcome the carrier flow restriction. VCSEL including multiple gain regions with tunnel junctions in between the gain regions are described in a non-patent literature publication entitled “Multistage Bipolar Cascade Vertical-Cavity Surface-Emitting Lasers: Theory and Experiment”, Knödl et al., IEEE Journal on Selected Topics in Quantum Electronics, vol. 9, No. 5, September/October 2003, pp. 1406-1414. This concept is applied to other systems including GaSb material system described in a non-patent literature publication entitled “Mid-IR GaSb-Based Cascade VCSELs”, Sanchez et al., IEEE Photonics Technology Letters, vol. 25, No. 9, 2013, pp. 882-884, and in a III-Nitride system and more specifically, in GaN system described in the U.S. Pat. No. 6,822,991 issued on Nov. 23, 2004, to Collins III et al., an U.S. Pat. No. 6,515,308 issued on Feb. 4, 2003, to Kneissl et al.

While all the designs having multiple gain regions have been very successful in increasing the output power in a single mode as well as brightness, there are still challenges in controlling polarization of the output laser beam which is a necessary requirement where high speed operation of VCSELs is needed for applications such as structured light generation, high speed optical I/O, Active Optical Cable (AOC), high speed data and telecom links, time of flight measurement for 3D imaging, just to mention a few. In most applications of high brightness VCSELs at high speeds, it is desirable that the VCSEL emission is in a single polarization state, preferably in a preferred linear polarization state. While prior art VCSELs have been designed that typically emit in a single polarization state (or in some cases multiple polarization states) but the orientation of the polarization is normally random and may change under different operating conditions.

There are methods known in the art for controlling the polarization orientation by introducing some form of birefringence into the resonant cavity, for example, by generating anisotropy in the gain region of the VCSEL structure in many different ways documented in the art (for example, United States Patent Application publication No. 20070098032 by Johnson et al. published on May 3, 2007, U.S. Pat. No. 5,412,680 issued on May 12, 1995, to Swirhum et al., U.S. Pat. No. 5,390,209 issued on Feb. 14, 1995, to Vakhshoori, U.S. Pat. No. 6,885,690 issued on Apr. 26, 2005, to Aggerstam et al., U.S. Pat. No. 6,785,318 issued on Aug. 31, 2004, to Matsui et al., U.S. Pat. No. 6,188,711 issued on Feb. 13, 2001 to Corzine et al., and European Patent Application Publication No. EP1104056 by Brunner published on May 30, 2001).

More recently, better polarization control has been realized by using a sub-wavelength linear grating (SWG). Sub-Wavelength Grating for polarization control is positioned at different levels depending upon the VCSEL design. For example, in a designed described in the U.S. Pat. No. 8,331,412 issued on Dec. 11, 2012, to Amann et al, and U.S. Pat. No. 733,522 issued on Feb. 19, 2008, to Ostermann et al., SWG is buried in the VCSEL structure preferably near a DBR or between DBR and active region. More commonly, SWG is positioned on top of the upper DBR or on the outer emitting surface of the VCSEL cavity (for example, U.S. Pat. No. 6,785,320 issued on Aug. 31, 2004 to Amos et al., U.S. Pat. No. 8,455,279 issued on Jun. 4, 2013, to Johnson et al., United States Patent Application publication No. 20070242715, by Gustaysson et al., on Oct. 18, 2007, PCT Application publication No. WO2011093885 by Fattal et al., published on Aug. 4, 2011, “Polarization stabilization of vertical-cavity top-surface emitting laser by inscription of fine metal integrated grating”, Jung-Hoon Ser, et al., Applied Physics Letters, vol. 66, 1995, p. 2769, “Reliable Polarization Control of VCSELs through Monolithically Integrated Surface Gratings: A Comparative Theoretical and Experimental Study”, Debernardi et al., IEEE Selected Topics in Quantum Electronics, vol. 11, No. 1, January/February 2005, pp. 107-116, “Efficient and Individually Controllable Mechanism for Mode And Polarization Selection in VCSEL Based on Common Localized Sub-Wavelength Surface Grating”, Gustaysson et al., Optics Express, vol. 13, No. 17, August 2005, pp. 6626-6634, “Polarization Control in Buried Tunnel Junction VCSELs Using a Birefringent Semiconductor/Dielectric Subwavelength Grating”, Ortseifer et al., IEEE Photonics Technology Letters, vol. 22, No. 1, January 2010, pp. 15-17).

It has been shown that most of the prior art methods either alone and/or in different combinations are proven to be effective only for polarization control in continuous wave (CW), quasi-CW (QCW) operation or for slow and long pulsing of the VCSEL. The polarization control is particularly effective after lasing stabilizes with the optical mode having the highest gain ultimately achieving a stable polarization state. For very short pulses and especially in the initial fast rising portion of a short pulse, the prior art approach is not very effective in obtaining linear polarization. At the leading edge of the pulse during fast pulsing of a VCSEL there is a fast high intensity optical pulse generated from gain switching or relaxation oscillation resonance effects. Because of the higher gain and short timescale the fast rising high intensity pulse lases in a random polarization state and may overcome any small polarization losses introduced into the cavity by optical anisotropy.

Therefore in applications where VCSEL operation for high speed pulsing in the initial gain switching resonance regime (for example in Q-switched mode) is important, the methods for polarization control implemented in the prior art design is not effective and new designs are necessary. In this invention new design for high output power high brightness VCSEL and VCSEL arrays operating in a stable linear polarization state. While it may appear that the concepts to obtain particular optimized properties of prior art VCSEL devices are applied in designing of the new VCSELs described in this application, VCSELs and VCSEL array devices designed according to this invention show linearly polarized output at high speed pulsing operation, including in the initial fast rise time gain switching regime. The VCSELs and VCSEL array devices are configured with electronic components in a surface mountable form for individually addressable, selected group(s), or/and parallel collective operation at high speed, in a process compatible with high volume manufacturing and packaging techniques according to current industrial standards.

### SUMMARY OF THE INVENTION

According to one aspect of the invention monolithically integrated high power, high brightness VCSEL and VCSEL arrays (VCSEL devices) are provided according to high volume manufacturing processes. In particular, VCSEL devices comprising monolithically integrated multilayer top and bottom DBRs (top and bottom mirrors/reflectors) forming a laser cavity to enclose a gain region comprising one or more quantum wells is provided. Each gain region is preceded or followed by a current and/or an overlapping mode confining aperture in the cavity to maximize optical output power in predetermined optical mode(s), preferably in a single optical mode for high brightness.

In a different aspect, gain and output power of VCSEL device is increased by providing a gain region having multiple gain segments in tandem, each gain segment including one or more quantum wells. In another aspect of the invention, each gain segment is preceded or followed by a current and/or an overlapping mode confining aperture preferably aligned centrally within the multiple gain segments of the VCSEL cavity to confine almost all the current in a very narrow region of the multiple gain segments to maximize optical gain and output power in a predetermined optical mode(s) from all the gain segments, and preferably in a single optical mode for high brightness.

In a variant aspect, to facilitate unrestricted carrier transfer and in particular minority carrier transfer, between each gain segment in tandem, a tunnel diode (junction) comprising heavily doped p⁺⁺ and n⁺⁺ region is provided between each gain segment to allow carrier tunneling between p and n sections located across the gain segments. Preferably, the p⁺⁺ and n⁺⁺ regions of the tunnel junction are positioned respectively, on the p- and n-side of each gain segment for unrestricted minority carrier flow.

In another embodiment multiple gain regions and a plurality of tunnel junctions there between provides very low electrical resistance and heat generation, thereby increasing current carrying capacity for higher output optical power and brightness.

In a different aspect, a VCSEL device incorporating multiple gain segments is provided with an extended cavity to facilitate mode diameter expansion to incorporate more optical power in a single mode for improved brightness. Extending the length of the cavity is achieved by incorporating a third reflector positioned at a relatively large distance compared to the distance between the two DBRs. The third reflector is positioned facing the emission surface of the VCSEL device. In addition the DBR positioned between the third reflector and the other DBR has a relatively low reflectivity such that lasing occurs in the cavity formed between the third reflector and the DBR distal to the third reflector beyond the intermediate low reflectivity DBR.

In a yet variant aspect of the invention a VCSEL with three reflectors and multiple gain segments in tandem with tunnel junctions there between, is provided for higher optical output power in a single optical mode thereby producing high brightness VCSEL. In one embodiment of the invention a three reflector VCSEL device having multiple gain segment is provided to achieve output optical power that is more than two orders of magnitude compared to the VCSEL device without the tunnel junctions and/or having a single gain segment.

In one embodiment of the invention high power, high brightness optical pulses are generated in a linear polarization state where the third reflector is deployed with a polarization selection means, such that the VCSEL according the principles of this invention operates in a linear polarization in fast pulsing mode including the duration of the initial fast gain switching regime of the pulse. In one aspect of the invention the polarizing means is applied to the third reflector in the form of a linear grating. In a variant embodiment, the linear grating is integrated with the third reflector.

In one aspect the principles of the invention may be practiced in top and bottom emitting (radiation transmitted through the substrate) configuration of VCSEL devices. Depending upon the emission wavelength in the bottom emitting configuration radiation is emitted through a light hole (light via) in the substrate or by deploying ultra-thin VCSEL device with substrate partially or completely removed to prevent absorption of radiation in the substrate. In a different embodiment an ultra-thin VCSEL device is provided on a thermal submount. In yet another aspect, the VCSEL device is constructed in surface mount configuration with or without peripheral electronic components, suitable for high speed Optoelectronic Integrated Circuits (OEIC) using a high volume, high throughput manufacturing and packaging environment.

### BRIEF DESCRIPTION OF THE DRAWINGS

A broad framework of the invention describing different aspects is presented in the specification which will be better understood and appreciated in conjunction with the drawing figures in which—

FIG. 1 shows schematic representation of a prior art VCSEL structure, a) the basic structure, and b) bonded to a submount;

FIG. 2 shows schematic of a high power VCSEL device, a) the physical structure of a VCSEL having multiple gain segments, and b) physical location of gain segments with respect to cavity standing wave modes;

FIG. 3 is a schematic diagram of one embodiment of a high power VCSEL in a) surface mountable configuration, and b) extended cavity three reflector configuration;

FIG. 4 is a schematic diagram of embodiments of a VCSEL cavity in a three reflector configuration, a) with the substrate, and b) without the substrate;

FIG. 5 is a schematic diagram of embodiments of a VCSEL cavity in a three reflector configuration, a) a flat external reflector, and b) a curved external reflector, respectively;

FIG. 6 schematically show exemplary external reflectors including, a) and b) flat reflector configurations, and c) curved reflector configuration;

FIG. 7 schematically represent effects of stress and the resulting strain in the epitaxial structure causing a) bow in the VCSEL wafer, and b) methods to partially or fully mitigate the bow;

FIG. 8 shows experimental single mode output power versus as a function of drive current for a high brightness VCSEL;

FIG. 9 schematically show an alternative design for an external reflector for polarization selection, a) a planar view, b) a cross sectional view of a flat third reflector, and c) a cross sectional view of a curved reflector, respectively;

FIG. 10 show measured reflectivity as a function of wavelength of a polarizing reflector similar to one shown in FIG. 9;

FIG. 11 is a schematic representation of different configurations of VCSEL including, a) polarizing external reflector, and b) polarizing integrated reflector;

FIG. 12 is a schematic representation of different embodiments including polarizing reflector configured in, a) bottom emission mode and b) top emission mode;

FIG. 13 represents a time response plot of a typical VCSEL device including a prior art VCSEL device in fast pulsing mode;

FIG. 14 is a measured time response of an exemplary VCSEL constructed according to this invention, operated in fast pulsing mode showing linear polarization behaviour;

FIG. 15 is a schematic representation of a monolithically constructed VCSEL array with a polarizing third reflector compatible with a high volume manufacturing process; and

FIG. 16 is an engineering drawing of a representative three reflector prototype VCSEL module.

### DETAILED DESCRIPTION

A broad framework of the principles will be presented by describing various aspects of this invention using exemplary embodiments represented in different drawing figures. For clarity and ease of description, each embodiment includes only a few aspects at a time. However, it should be understood that different aspects of different embodiments may be combined or practiced separately, in for best mode practice. To keep the description short, drawing figures are labelled to identify similar elements or elements having equivalent functions with similar reference numeral in which the first number always refers to the figure number (e.g., 101, 201, 301, etc. will refer to a substrate in all the drawing figures). Many different combinations and sub-combinations of the representative embodiments to be described within the broad framework of this invention, that may be apparent to those skilled in the art but not explicitly shown or described, should not be construed as precluded.

### High Output Power, High Brightness VCSEL:

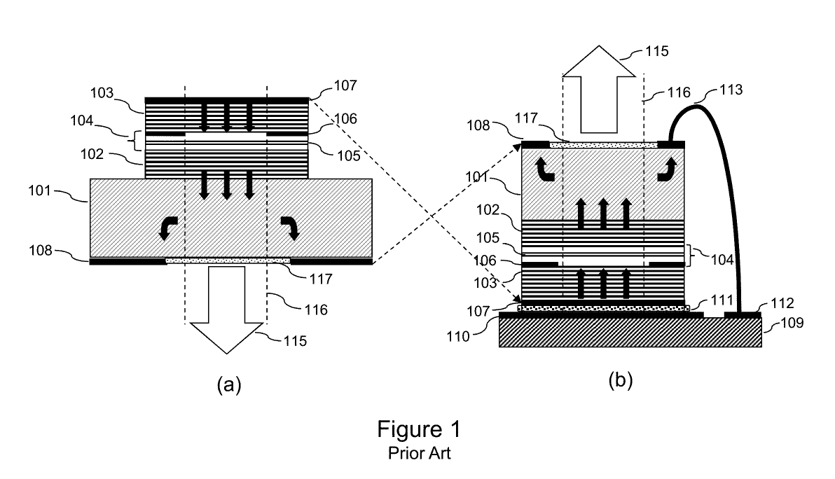

FIG. 1 represents a schematic representation of a basic VCSEL device. For ease of description, the inventive concepts will be explained in the context of the basic VCSEL structure shown in FIGS. 1a and 1b. Although most figures show a single VCSEL device to keep the description simple, it should be understood that the same concepts apply to VCSEL array devices. In the following description the term VCSEL device will be used generically for single VCSEL device as well as VCSEL arrays, unless otherwise mentioned. FIG. 1a shows schematic structure of the part of a VCSEL device that generates and amplifies light. Such structures are typically grown using methods of epitaxial growth well documented in the art.

The basic epitaxial structure shown in FIG. 1a is usually grown sequentially and preferably in a single growth run, on a substrate 101. Therefore, the substrate end of the device is generally referred as ‘bottom’ and the surface of the substrate on which the first epitaxial layer is grown is the top surface of the substrate. Each subsequent epitaxial layer is grown on top surface of a previously grown layer, and the last layer in the sequence is referred as top layer or simply, the ‘top’. Therefore, ‘bottom’ and ‘top’ is always referred in the context of the substrate. It should be understood that there are post epitaxial growth processing sequences (for example, etching, photolithography, selective growth, physical or chemical vapour deposition, etc.) that may be performed on the top or bottom surface.

A first stack of layers 102 grown on the top surface of the substrate is referred as a first or bottom reflector. Typically, the reflector is a semiconductor Distributed Bragg Reflector (DBR). However, other types of reflector such as dielectric mirror grown and hybrid bonded are also applicable. A light emitting region (also gain region) 104 is grown on top of the bottom DBR. The light emitting region includes many different layers including at least one quantum well (QW) or preferably, multiple quantum wells (MQW) 105. A second reflector 103, also typically a semiconductor DBR, is grown on top of the gain region (top DBR), such that a resonant cavity enclosing the gain region is formed between the top and bottom DBRs. The top and bottom DBRs are often doped oppositely, so as to provide a p-n junction. Electrical connection to the junction is provided through metal contacts 107 and 108, known as top and bottom contacts, respectively. The bottom contact may be provided at the bottom surface of the substrate (in FIG. 1a) or on an extended section of the bottom DBR (102). In this example the top contact covers the entire VCSEL surface but the bottom contact 108 is in the form of a ring to leave an emission window open.

Upon applying a potential difference between the top and bottom ends of the VCSEL structure, a drive current is set up in the vertical direction (current path shown with heavy arrows in FIG. 1a) and light is generated in the light emitting region. The light generated between the top and bottom DBRs experience gain. Therefore, the region within the cavity is also conventionally known as a gain region. For better efficiency, a current applied between the top and bottom DBRs is confined within an annular space by a current confining aperture 106 formed by controlled oxidation of a pre-designated epitaxial layer (not shown) having a particular composition for ease of oxidation. The current confinement aperture also confines the optical mode 116. The aperture size in relationship with the other properties of the laser resonant cavity determines the transverse mode properties such as single mode versus multi-mode operation, etc.

In this particular example, reflectivity of the bottom DBR (102) is set lower than the reflectivity of the top DBR (103), so that laser output 115 is emitted from the window in the substrate (bottom emitting VCESL device). Often, an antireflection coating 117 is applied to the window. In general, one surface is the emission surface and the surface opposite from the emission surface is used for bonding the device (bonding surface), as a matter of choice. In this particular example the bottom surface of the substrate is the emission surface and the top surface of the top DBR is the bonding surface. However, it is not necessary for the laser output to be emitted from the bottom surface of the substrate. By suitably selecting the reflectivity of the top DBR to be lower than the bottom DBR, laser output may be emitted from the top DBR surface of the VCSEL (top emitting VCSEL device). For a top emitting VCSEL device the top surface of the top DBR and the bottom surface of the substrate will be the emission and bonding surfaces, respectively.

While the present invention can be practiced in either configuration, for high power output application the bottom emitting configuration is preferred. In the bottom emitting configuration the VCSEL device side rather than the substrate is bonded directly to a thermally conducting submount for efficient cooling. An example is shown in FIG. 1b where the configuration shown in FIG. 1a is flipped in the vertical direction (with reference to the drawing plane) indicated by broken line in the drawing figure, such that the bonding surface with the contact 107 is facing down and the emission surface with contact 108 is facing vertically up (with reference to the drawing plane). The VCSEL device is mounted onto a submount 109 using an electrically and thermally conducting bonding material 111, such as solder, to bond the top contact 107 to a contact pad 110 on the submount. The VCSEL bottom contact 108 is connected to a second contact pad 112 using a wire bond 113. Thus VCSEL device is operated by applying a drive current between pads 110 and 112.

The submount may be of many different types including a thermal submount, a printed circuit board with a heat conducting surface, a thermal submount having wrap around pads or electrical and thermal vias connecting to contact regions from the top to bottom surfaces, or a suitable combination thereof, usually used for efficient heat transfer away from the VCSEL device, as described in the U.S. Pat. No. 8,675,706 issued on Mar. 18, 2014, to Seurin et al., and United States Patent Application Publication No. 2013/0163627 published by Seurin et al on Jun. 27, 2013, and co-owned by the Assignee of this application, Princeton Optronic Inc. Mercerville, N.J. Contents of these two patent literature publications are being incorporated by reference in their entirety.

While the output power can be increased by applying more drive current to the gain region, the output power is ultimately limited by factors like current rating of the VCSEL device, pumping efficiency, optical power available in the gain region, power distribution in higher order modes which particularly limits the brightness of the VCSEL device, and limitations from peripheral devices, such as cooling efficiency. For high brightness, single transverse mode operation is desirable which is achieved by limiting the current confining aperture diameter such that loss in higher order modes is increased without introducing extra loss in the dominant (single) transverse mode. Power in a single mode may be increased in one of many ways that will be described shortly.

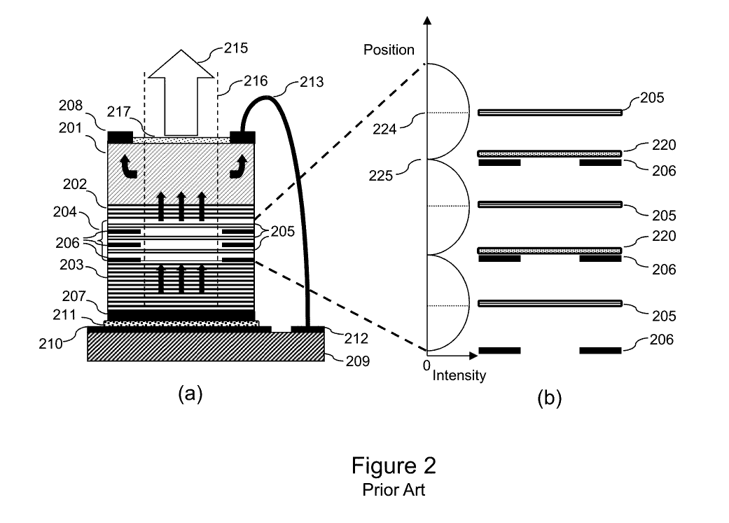

One way to increase output power is to enhance the gain capacity. FIG. 2 schematically shows a VCSEL structure designed for higher gain. More specifically, the structure shown in FIG. 2a is a bottom emitting VCSEL device bonded to a submount similar to the one shown in FIG. 1b. Description of each labeled element is substantially similar to the configuration shown in FIG. 1b and that description will not be repeated for brevity. The configuration shown in FIG. 2a is different from the one shown in FIG. 1b in respective gain regions 204 (and 104). The gain region in this configuration has multiple gain segments, each one including a QW or preferably, MQW 205, and each segment may be described as a MQW group for the ease of description. There are confinement layers between the MQW groups that are not shown or labeled for clarity. In this example, three MQW groups are shown but that number may be different. Each MQW group is separated from an adjacent MQW group by apertures 206.

While the example in FIG. 2a shows apertures placed between each gain segment that criterion is not absolutely necessary. Alternatively, apertures may be placed between selective MQW, and/or between the top MQW group and the top DBR stack 203 or in the bottom DBR 202. As mentioned earlier, there are other layers between the MQW groups and some of them may be in close contact with an oppositely doped layer thereby forming a slightly reverse biased junction, which may partly restrict the carrier flow, and in particular minority carrier flow in the gain region. To overcome this effect, a tunnel diode (or a tunnel junction) is placed between the MQW groups to ease the flow of charge carrier in the gain region. A reverse biased tunnel junction has a negative resistance and therefore provides charge carriers in the gain region.

It is noted that it is not only sufficient to have several MQW groups in the gain region their placement within the gain region is also instrumental in maximizing gain. More detail of the gain region is shown in the adjacent FIG. 2b. In particular, in FIG. 2b a plot of coherent resonant laser modes of the laser cavity (formed between the bottom and top DBRs 202 and 203, respectively) is shown. The intensity plot shows that laser resonant modes show a standing wave pattern with periodic maximum and minimum intensities 224 and 225 (only one set labeled for clarity), respectively, that are similar to antinode and node, respectively, of a standing wave. Depending upon the length (or height in the context of the figure), there may be multiple antinodes and nodes in the standing wave.

In order to maximize the gain in the cavity each MQW group 205 is placed at an intensity maximum (antinode) of the standing wave to obtain maximum optical power and gain conversion from the MQW, whereas each aperture 206 is placed at the minimum (node) of the standing wave to minimize optical attenuation of the mode at the aperture (right hand side of FIG. 2b). The tunnel diodes 220 are placed near the apertures where the flow of charge carriers from the reverse biased tunnel junction may be contained in the physical space of the aperture, such that maximum charge carriers are available in the most relevant volume of the gain region. To further ensure this effect, all the apertures are preferably aligned (in a column in the perspective of the drawing figure) within the gain region to maximize power in a particular desired mode. It is noted that the basic description of the gain region is applicable to all high power high brightness VCSEL devices to be described in the following sections.

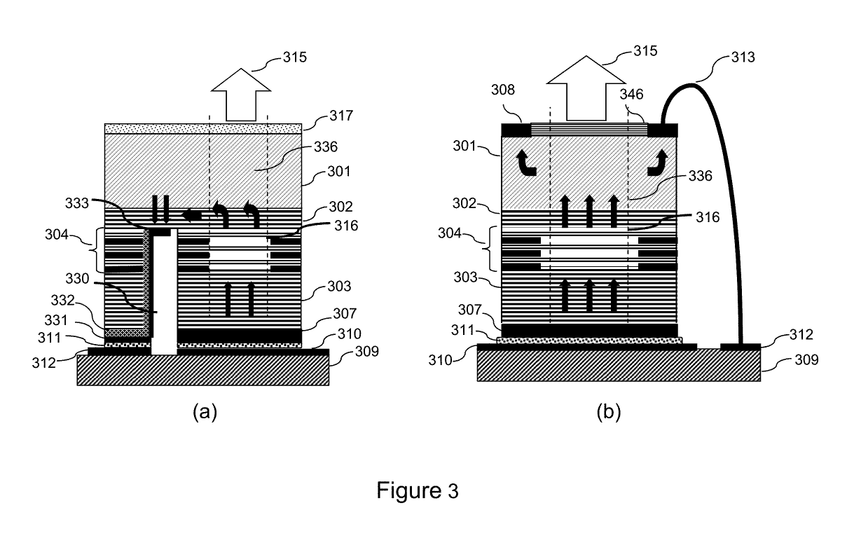

In an embodiment particularly suited for high volume manufacturing and assembly process, a preferred configuration for the VCSEL device is to have both contacts on the same side of the device (both contacts on top or bottom surface) that are readily adaptable for surface mounting process. An exemplary configuration for this embodiment is shown in FIG. 3, and in particular, in FIG. 3a. The description of similarly labeled elements from FIGS. 1 and 2a is applicable to FIG. 3 as well. That description will not be repeated. The basic structure of the VCSEL device shown in FIG. 3a includes all the same elements as the one shown in FIG. 2a, including those of the gain region (several MQW groups separated by tunnel diodes in between). The top contact 307 is substantially similar to the top contact shown in FIGS. 1 and 2a.

However, the bottom contact to either the substrate (208 in FIG. 2a), or the bottom DBR which is located on the opposite side of the top contact 207 in VCSEL device in FIG. 2a is configured differently in this embodiment. More detail description is provided in the U.S. Pat. No. 8,675,706 issued on Mar. 18, 2014, to Seurin et al., and co-owned by the Assignee of this application, Princeton Optronic Inc. Mercerville, N.J. That description is being incorporated by reference in its entirety. More specifically, a trench is 330 is fabricated by selectively etching the VCSEL epitaxial layers down to the bottom DBR 302 as shown in the example in FIG. 3a, or in some cases further down to the substrate 301. Electrical contact 333 is made to the bottom DBR (or to the substrate 301). The electrical contact 333 brought through the trench to connect to a contact pad 331 on the top side of the VCSEL device. An insulating layer 332 is deposited under the contact in the gain region 304 and top DBR 303 to prevent current flowing directly to the top contact 307, bypassing the gain region 304. The current flow path through the VCSEL device is indicated by heavy arrows. It is noted that both the contacts 331 and 307 accessible on the same side of the VCSEL device facilitates surface mounting to electrical bonding pads 312 and 310, respectively on the submount 309.

### High Power in a Single Mode:

One drawback of having multiple MQW groups in the gain region is that the increase in output power is channeled in fundamental as well as higher order modes. While the total laser power increases, it does not increase brightness. Brightness is higher when majority of the power is confined in a dominant mode, preferably a fundamental transverse mode. But to restrict the operation to single mode, the diameter of the aperture(s) has to be small enough to sufficiently attenuate higher order modes. In order to further increase the power in a single mode, the aperture diameter must increase to increase the mode diameter in the cavity so that the mode draws power from a larger volume of the multiple groups of quantum wells. A simple way to achieve that is to change the cavity parameters, and particularly the length (or height in this context) of the cavity. Increasing the cavity length increases the diameter of the lasing modes and means a larger aperture can be used to control single mode operation thus increasing the gain volume to obtain higher power.

It is not practical to significantly increase the distance between the first and second DBRs to increase the cavity length. A more practical solution is to extend the cavity using a third reflector which is placed facing the emission surface of the VCSEL device but at some distance away from the VCSEL device shown in FIG. 2a. In the extended cavity configuration one of the DBRs with the third reflector functions as an equivalent reflector of the extended laser cavity thereby facilitating expansion of the mode diameter. The bottom emitting device described in reference with FIG. 2a is readily adaptable to configure an extended cavity VCSEL device shown in FIG. 3b. The basic VCSEL device structure configured in the extended cavity form includes all the features of the device shown in FIG. 2a. Those features will not be described again.

The cavity is extended by incorporating a third reflector 341 on the bottom surface of the substrate instead of the antireflection coating (217 in FIG. 2a) on the emission surface. The third reflector may be implemented using another DBR, a dielectric reflector stack, or a metal coating that is easily deposited on the bottom surface of the substrate in a post processing step (in reference to the epitaxial layers growth step). In the example shown in FIG. 3b, the third reflector coating 346 in combination with the bottom DBR 302, functions as the second reflector of the extended cavity. The cavity length (or height) is extended by a distance equivalent to the thickness of the substrate. One advantage of configuring the third reflector in this manner is that the third reflector is not an external component requiring precision alignment and/or precision mounting with the basic VCSEL device structure.

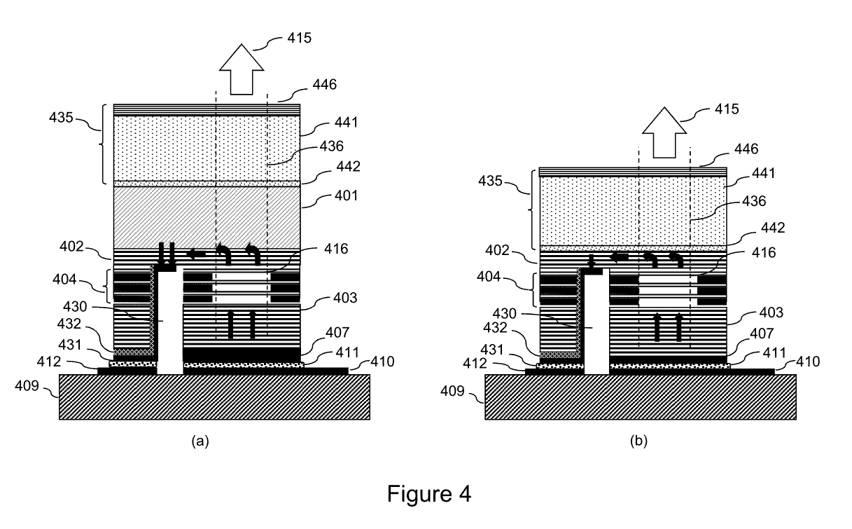

Another simple implementation of extending the cavity length using a third reflector is shown in FIG. 4. The configurations shown in FIGS. 4a and 4b have all the basic features of the surface mountable bottom emitting VCSEL device shown in the FIG. 3a. The basic VCSEL device features of configuration shown in FIGS. 4a and 4b will not be described. The third reflector 435 in this configuration comprises a transparent substrate 441 including a partially reflective coating 446 deposited on one surface and the other opposite surface is bonded to the bottom surface of the VCSEL device substrate 401 using a bonding element 442 in between. The bonding element 442 is a combination of a transparent adhesive and antireflection coating(s) designed to minimize optical reflection of the lasing wavelength at the interface between the VCSEL device substrate 401 and the transparent substrate 441. The resonant optical mode 436 in the external part of the three reflector cavity propagates in the VCSEL substrate and the transparent substrate and propagates between the bottom and top DBRs (416) in the gain region. The laser output beam 415 is emitted out of the partially reflective surface of the third reflector.

One disadvantage of the laser beam emission from the substrate in the bottom emitting configuration is that the part or all of the laser emission may be absorbed in the substrate depending upon the emission wavelength, particularly for wavelengths shorter than the absorption edge of the substrate material. In a three reflector cavity the substrate would absorb the resonant cavity mode between the bottom DBR and the third reflector. One option to circumvent both the problems is to remove the substrate so that the output beam exits directly from the bottom DBR. In one embodiment of the invention shown in FIG. 4b, an “Ultra-thin” VCSEL structure is provided. Detail description of the process for fabricating the “Ultra-thin” VCSEL device provided in U.S. patent application Ser. No. 14/634,902 filed by Q. Wang et al. on Mar. 2, 2015. Contents of this application are co-authored by some of the inventors of this application and co-owned by Princeton Optronics Inc. Mercerville, N.J., and is being incorporated by reference in its entirety.

The basic device structure is practically identical to the one shown in FIG. 4a. In order to implement the “Ultra-thin” VCSEL device structure shown in FIG. 4b, the basic VCSEL device with the substrate 401 (FIG. 4a) is bonded to a carrier substrate (or a carrier) prior to partially or completely removing the substrate. Since the structure is very fragile after removing the substrate, the VCSEL device still bonded to the carrier, is diced in to individual devices or arrays, and mounted on the submount 409. The process up to this step is similar for a two or three reflector VCSEL device. The third reflector 435 is bonded to the thinned VCSEL device using the process described in reference with FIG. 4a; however, the cavity length is extended only by the thickness of the transparent substrate 441. The laser output 415 is emitted out of the third reflector.

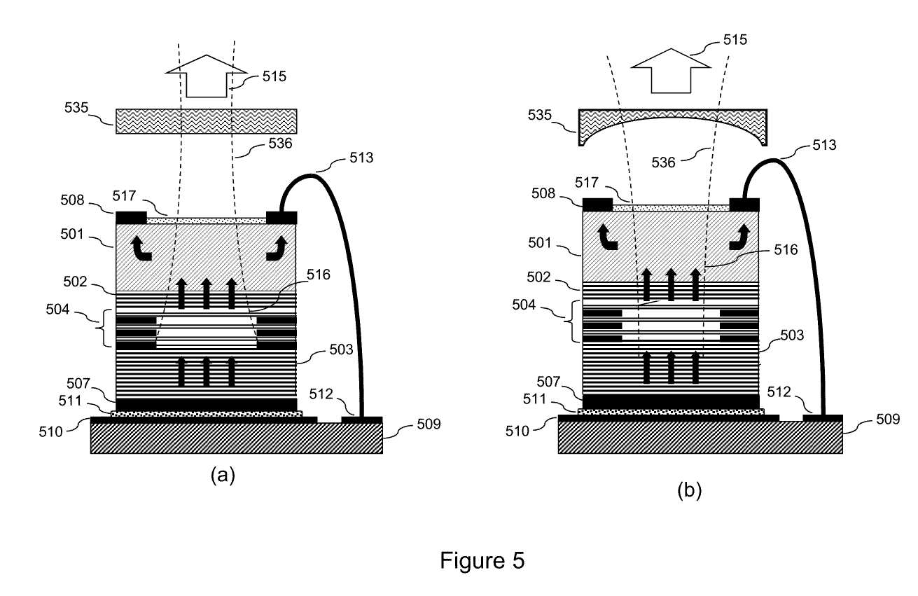

The extended cavity configurations described earlier are easy to implement because the steps do not require precision alignment and bonding of external components. Furthermore, the entire process may be carried out at wafer level processing compatible with large scale manufacturing and packaging. However, it does not provide enough flexibility in extending the cavity length further. In another embodiment an external third reflector may be used to configure an extended cavity VCSEL device. Some exemplary configurations of extended cavity VCSEL device using external third reflector are shown in FIG. 5. The basic design of the configurations shown in FIGS. 5a and 5b are quite similar to the bottom emitting VCSEL device shown in FIG. 2a and the general description provided there still applies. The two configurations shown in FIGS. 5a and 5b use an external reflector 535 (flat and curved reflector, respectively) placed facing the emission surface above the substrate 501. The reflectivity of the bottom DBR in this configuration is set to a low value to prevent self lasing operation between the bottom and top DBRs.

The third reflector is aligned to the VCSEL device, such that the combined in-phase reflectivity of the bottom DBR and the third reflector is sufficiently high for lasing to occur in coherent modes 516 (in the VCSEL cavity) and 536 (in the external part of the extended cavity). The combined reflectivity is optimized for highest laser output power 515 through the third reflector. Due to the extended cavity length, it is possible to increase the aperture (not shown in the figure) diameter without significantly affecting single mode operation, thereby facilitating conditions for high output power and high brightness output emission. One advantage of a curved external third reflector shown in FIG. 5b is wavefront matching between the mode in the cavity external to the VCSEL device (536) and the mode inside the VCSEL cavity (516) is better which results in low loss and maximum output power laser emission. Various curvature mirrors can be used, both concave and convex to match the optical properties of the VCSEL cavity, the distance from the VCSEL and any thermal lensing that can occur in the VCSEL epitaxial region or substrate.

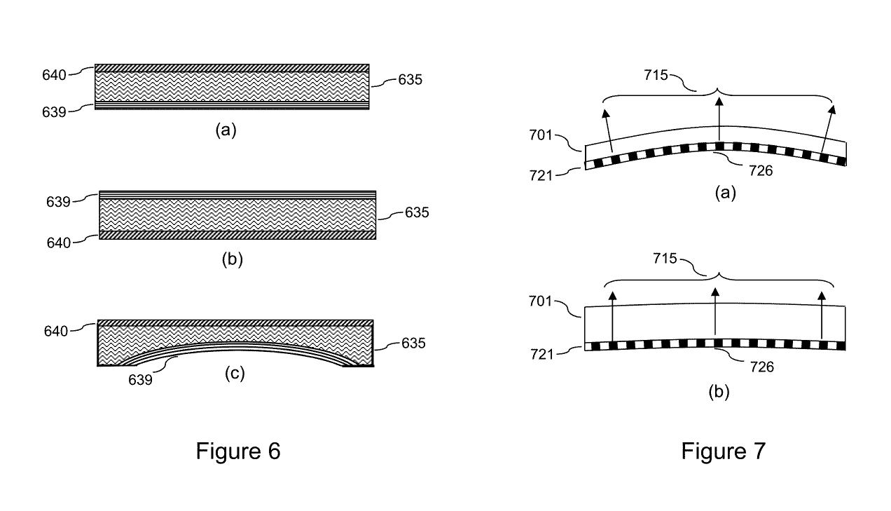

FIG. 6 shows some of the third reflector configurations in more detail. More specifically, FIG. 6(a) shows a flat mirror substrate 935 with a reflective coating 639 on one side that is placed facing the DBR of the VCSEL device. The opposite side of the substrate includes an antireflection coating 640 to avoid destabilization of the VCSEL laser cavity resonant mode that may result from reflections from opposite surface. FIG. 6(b) shows an alternative reverse arrangement with the reflection coating 639 on the side away from the VCSEL device and the antireflection coating 640 facing the VCSEL device. Little longer cavity length is achieved using the external reflector in this configuration. FIG. 6(c) shows the structure of a curved reflector with the reflection coating 639 on the curved surface facing the VCSEL and the antireflection coating 640 on the opposite flat surface.

As mentioned earlier, one challenge in using an external reflector extended cavity is in precision alignment of the reflector. The problem is particularly difficult when the VCSEL device surface is not flat or has a bow. The problem can be understood better in view of FIG. 7. During normal processing of VCSEL device wafers strain from the epitaxial growth and the subsequent fabrication processes may result in the wafer to bow or warp as shown in FIG. 7a. The stress and resulting strain in the VCSEL epitaxial structure 721 results in a bow 426 to the wafer. Depending upon the composition and thickness of epitaxial layers, and structures fabricated therein, and relation of the strain to the substrate 701, the bow can be in either direction. The consequence of having a bow is that the directions of output laser emission 715, and in particular, output laser emission from a VCSEL array will not be parallel.

In a basic two reflector VCSEL array output laser emission from each VCSEL will diverge resulting in a divergent beam. In an extended cavity three reflector using an external reflector, the bow in the wafer would cause misalignment of emission from VCSELs resulting in a reduction of power and a corresponding reduction in brightness. The bow may be reduced by applying a strain compensation layer on the bottom surface of the substrate as has been described in a U.S. patent application Ser. No. 14/634,902 filed by Q. Wang et al. on Mar. 2, 2015. Contents of this application are co-authored by some of the inventors of this application and co-owned by Princeton Optronics Inc. Mercerville, N.J., and is being incorporated by reference in its entirety.

However, in some designs and applications for two and three reflector VCSEL device it may not be practical to use strain compensation as described in the above cited pending application. In one embodiment of the invention, an alternative approach is provided. It is noted that the problems arising due to bow in the wafer is less severe in thicker wafers as shown in FIG. 7b. Typically, standard wafer thickness for VCSEL device is between 100-400 mm, and more preferably about 250 mm. In the devices fabricated according to this invention, wafers thicker than 400 mm, and preferably between 0.5-0.8 mm significantly reduce bow and provide more parallel laser emission in two reflector VCSEL array and better alignment with the third reflector in a three reflector VCSEL array.

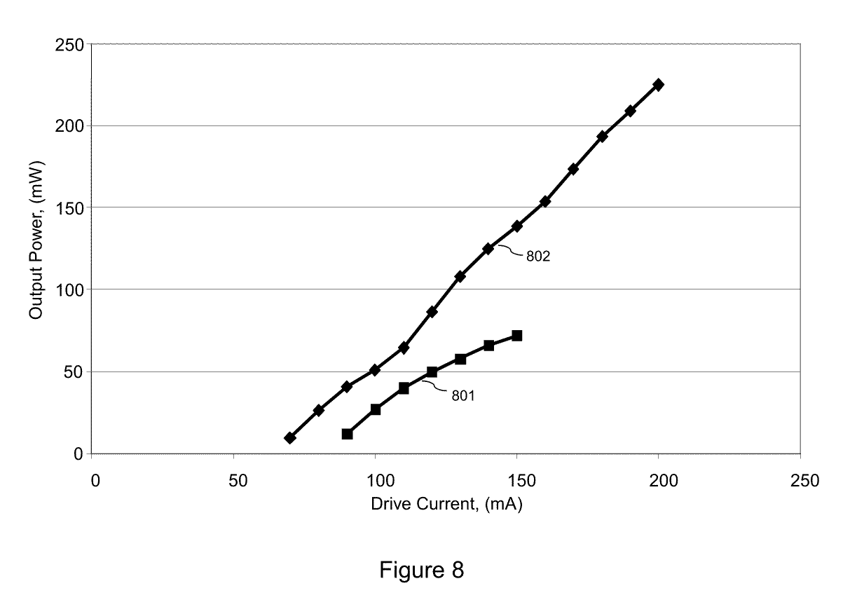

FIG. 8 shows output characteristics of a single VCSEL device configured with an external third reflector similar to the one shown in FIG. 5a. The graph in FIG. 8 shows single mode output power plotted (y-axis) as a function of drive current (x-axis). The exemplary VCSEL device has a gain region with three MQW groups and tunnel junctions in the gain region. The output power from the exemplary device is shown in trace 802. A single mode output power of about 230 mW is measured. The output power varies almost linearly until a drive current of about 200 mA and does not show signs of saturation. The second trace 801 is from an extended cavity VCSEL device that does not incorporate all the principles of this invention, and in particular, has a gain region with a single MQW region. The output power tends to saturate at about 70 mW around 150 mA of drive current. It is noted that single mode output power for a standard two reflector VCSEL device is typically <5 mW.

### Linear Polarization in VCSEL Device:

In general, there is spatial symmetry in a basic VCSEL device structure. Therefore, lasing in VCSEL device occurs with random polarization. If there is even a slight optical anisotropy (intentional or unintentional) the symmetry is broken. In that case lasing occurs in a fixed polarization state, usually a linear polarization state aligned to the lowest optical loss path. In some applications of VCSEL device lasing in a linearly polarized in a specified dimension is preferred. In some prior art design, anisotropy is introduced by intentionally adding strain in the QW region, or by using non-symmetric device forms for example, by using non symmetric geometry of the aperture, or the mesa structure. These methods are reasonably effective when VCSEL device is operated in CW mode or quasi-CW (QCW) mode. In pulse mode operation, introducing anisotropy for polarization control is effective only when pulse duration is long and pulsing speed is slow. Under these operating conditions, there is sufficient time for the resonant optical mode to stabilize into a linear polarized state.

However, for a fast pulsing application using a very short pulse, and especially at a leading edge of a fast rising pulse, initial high intensity optical pulse in a VCSEL device is generated by a gain switching mechanism or relaxation oscillation resonance effects. Due to the higher gain and short timescale, the high intensity pulse lases in random polarization and overcomes a small polarization loss introduced in a cavity arising due to optical anisotropy introduced by the methods mentioned earlier. Therefore, other polarization loss mechanism must be present such that the VCSEL device output emission is in a desired polarization state, preferably a linear polarization state even during the initial fast rise time regime during fast pulsing operation.

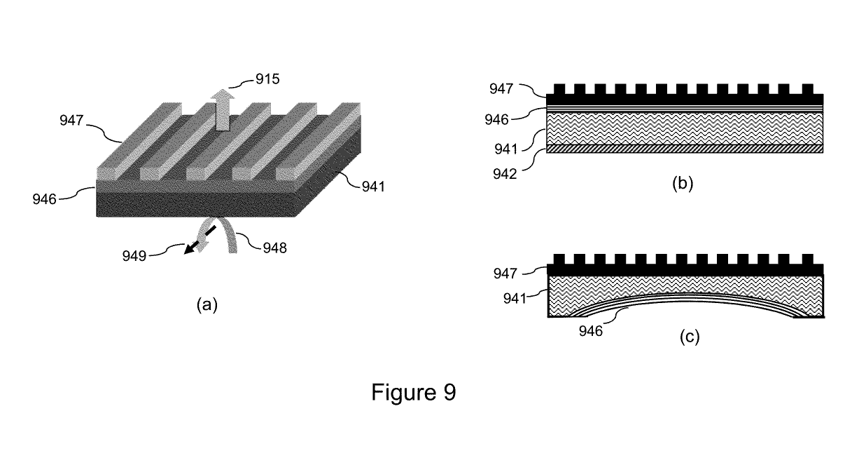

In one embodiment of this invention, a VCSEL design having a mechanism for strong polarization selection is presented. The design is particularly suited for and easily adaptable, in an extended cavity VCSEL device described in reference with FIGS. 3b, 4 and 5 in the previous section for generating a linearly polarized high brightness output. FIG. 9 schematically shows a new reflector design that would provide high power, high brightness output with strong polarization selection. As described earlier, that for an extended cavity VCSEL device, the third reflector is an essential element for lasing to occur. Therefore a third reflector having a built-in strong mechanism to select a dominant polarization state would force the VCSEL device to operate with a linear polarization, even when operated in the initial fast gain switching regime.

More specifically, FIG. 9a shows an example of a third reflector suitable for strong polarization selection and single mode operation. The reflector comprises a transparent substrate 941 coated with a combination of a reflective coating 946 and a custom designed grating 947. The grating design is customized for different output wavelengths, such that the grating does not form a laser cavity with the reflective coating or with other DBRs of the VCSEL cavity. A reflector so designed exhibits very high reflectivity in one linear polarization state (shown with an arrow 948) and a very low reflectivity for the orthogonal polarization (shown with a broken arrow 949).

The polarization selective design may be implemented in a very convenient way in the flat and curved reflectors described earlier in reference with FIG. 6. Some examples of polarization selective reflectors are shown in FIGS. 9b and 9c for a flat reflector and a curved reflector, respectively. More specifically, a cross section of a polarizing flat reflector shown in FIG. 9b comprises a transparent substrate 941 coated with a reflective coating 946 on one surface and a grating 947 constructed on it. The other opposing surface of the transparent substrate is coated with an antireflection coating 942 to avoid spurious lasing. A curved polarization selective reflector shown in FIG. 9c is slightly different. The substrate 941 is a curved transparent substrate. The curvature may be selected to optimize optical mode matching between the external and the internal sections of the extended cavity. A reflective coating 946 is deposited on the curved surface while a grating 947 is constructed on the flat surface of the substrate. Those skilled in the art would be able to appreciate that the new reflector design offers enormous flexibility in shapes, size and optical properties that can be achieved. In addition, the reflectors may be produced in large scale manufacturing environment. The reflectors may be configured with pre-designed VCSEL devices as well without having to modify the entire VCSEL device.

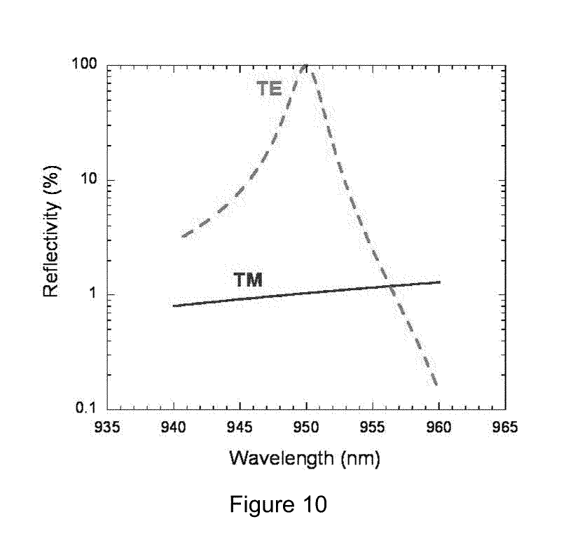

FIG. 10 shows polarization properties of a polarization selective reflector designed according to the description presented earlier. More specifically, the reflectivity data is obtained for a reflector designed to operate at 950 nm. The graph shows reflectivity (y-axis) as a function of wavelength (x-axis) for two different linear polarization components (TE and TM). For the TE polarization mode the reflectivity is almost 100% at the desired wavelength and drops quite sharply. For the orthogonal TM polarization mode, reflectivity is about 1% in the entire wavelength range.

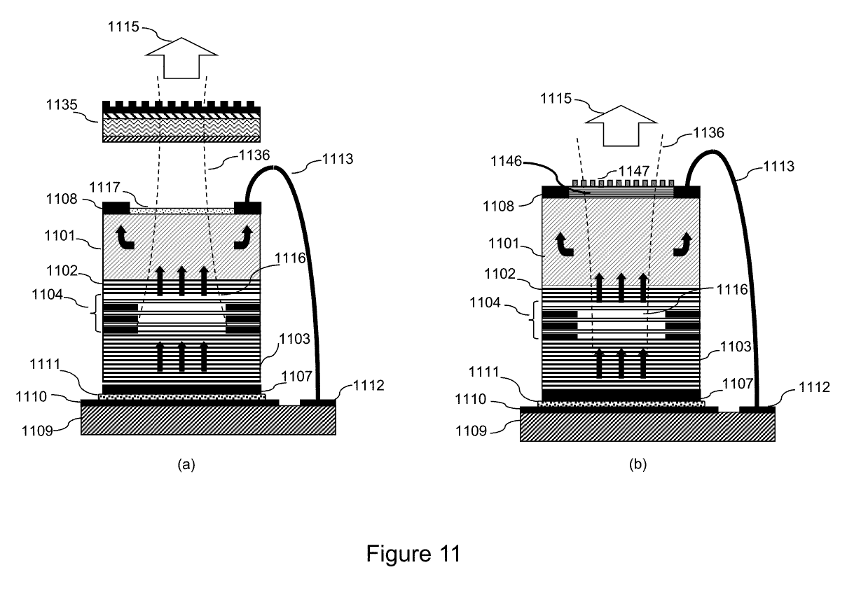

FIG. 11 shows exemplary embodiments of VCSEL device where the polarization selective reflector is applied to achieve high power and high brightness in a desired linear polarization state. More specifically, FIG. 11a shows a bottom emitting VCSEL device with an extended cavity implemented through an external third reflector, very similar to the configuration described in reference with FIG. 5a. The basic description of the device structure and function in reference to FIG. 5a also applies for the configuration shown in FIG. 11 except, the external third reflector is replaced by a polarization selective third reflector shown in FIG. 9b. It should be noted that the flat polarization selective third reflector (FIG. 9b) may be replaced by an equivalent curved reflector (FIG. 9c) for substantially similar performance.

An alternative embodiment of a polarization selective three reflector VCSEL device is shown in FIG. 11b. The basic design is substantially similar to the configuration shown in FIG. 3b and the description of the structure and functioning provided in reference with FIG. 3b still applies. In this configuration the third reflector is integrated with the VCSEL device by applying a polarization selective reflector having a reflective coating (1146) and a grating (1147) on the bottom surface of the substrate over the emission window. The advantage of an integrated polarizing reflector is that the third reflector may be applied in a simple post processing step and does not require precision alignment and bonding.

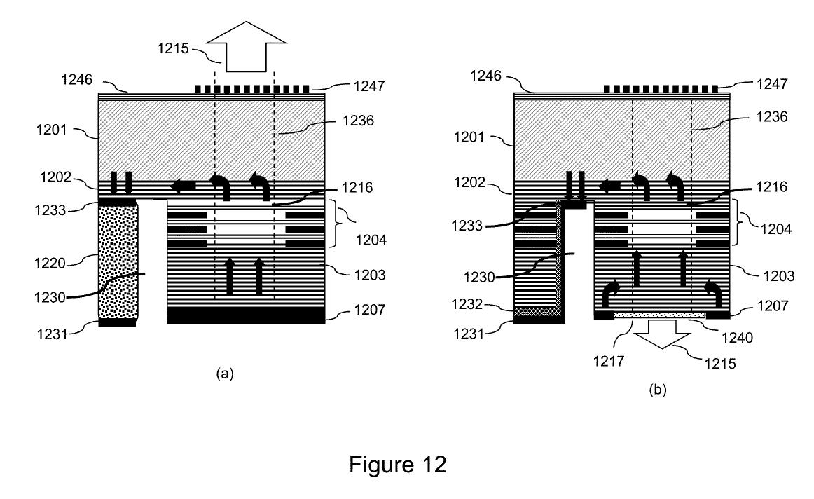

In a different embodiment shown in FIG. 12, a polarization selective reflector is integrated with a surface mountable VCSEL device described in reference with FIGS. 3a, 4a and 4b. While only one example is shown in FIG. 12a, it is to be understood that other possible designs within the broad framework are not precluded. More specifically, the description for a surface mountable bottom emitting device shown in FIGS. 3a and 4a is applicable to the VCSEL device shown in FIG. 12a. There are minor differences in the implementation to provide a contact from the bottom of the VCSEL device to the top of the VCSEL device in order to provide both contacts on the same side of the VCSEL device (both on top in this example).

More specifically, referring back to FIG. 12 a, in an area away from an optical mode path (1216 and 1236) on the top surface, a trench 1230 is selectively etched into the VCSEL epitaxial layers to expose a small area of the bottom DBR 1202 (shown in this example) or to the substrate 1201. An electrical connection 1233 to the exposed part of the bottom DBR (or the substrate) is made using a gold bump 1220 having substantially the same thickness as the VCSEL device structure above the bottom DBR (or the substrate) which is then connected to a contact region1231 coplanar with the top contact layer 1207 on the top side of the VCSEL device. The third reflector in this configuration is applied on the bottom surface of the substrate in the area of the optical mode path. The third reflector comprises a reflective coating 1246 in contact with the bottom surface of the substrate followed by a grating 1247 for the polarization selection. The laser output 1215 is a high power and high brightness emission having a linear polarization state.

It is noted that the discussion so far is focused on bottom emitting VCSEL device which is the more common configuration for high output power due to the fact that the VCSEL device can be mounted closer to a heat dissipating or cooling device surface. However, there are applications where a top emitting VCSEL device is a better choice. In the next example shown in FIG. 12b a polarization selective reflector is applied to a top emitting VCSEL device. More specifically, the basic VCSEL device structure is very similar to the one described in reference with FIG. 3a except for a few minor alterations that is easily implemented during the normal fabrication process. Referring now to FIG. 12b, the reflectivity of the top DBR 1203 is selected to be substantially lower than the reflectivity of the bottom DBR 1202. Furthermore, the reflectivity of the bottom DBR is selected according to a criterion such that the combined in-phase reflectivity of the bottom DBR and the third reflector (to be described shortly) is higher than the reflectivity of the top DBR, such that the laser output 1215 is emitted through a window in the top contact 1207. The window may be optionally coated with an antireflection coating 1217.

The third reflector in this configuration is implemented by applying a reflective coating 1246 and a grating 1247 on the bottom surface of the substrate in a manner described earlier in the context of the configuration shown in FIG. 12a. An electrical contact from the bottom DBR 1202 (or the substrate 1201) to a contact region 1231 of the top surface (coplanar with the top contact 1207) is provided through a trench 1230 as described in reference with FIG. 3a. That description will not be repeated. The structure is surface mounted on a submount (not shown) to provide drive current to the VCSEL device through respective matching contact pads on the submount (not shown) similar to the ones shown in FIG. 3a.

It can be appreciated that the extended cavity VCSEL device in surface mountable forms shown in FIGS. 12a and 12b may be surface mounted (without any wire bonding) directly to matching bonding pads on a submount with heat dissipation or cooling devices, and with or without peripheral electronic components to construct optical modules. In one embodiment, the submount may be a thermal submount having matching contact pads on both surfaces, such that the submount may be mounted to a printed circuit board or another suitable platform shared with peripheral electronic components. In a variant embodiment, external optical components may be used for beam shaping required for some applications. These and other options are well documented in the art including co-owned patents and patent applications publications mentioned earlier.

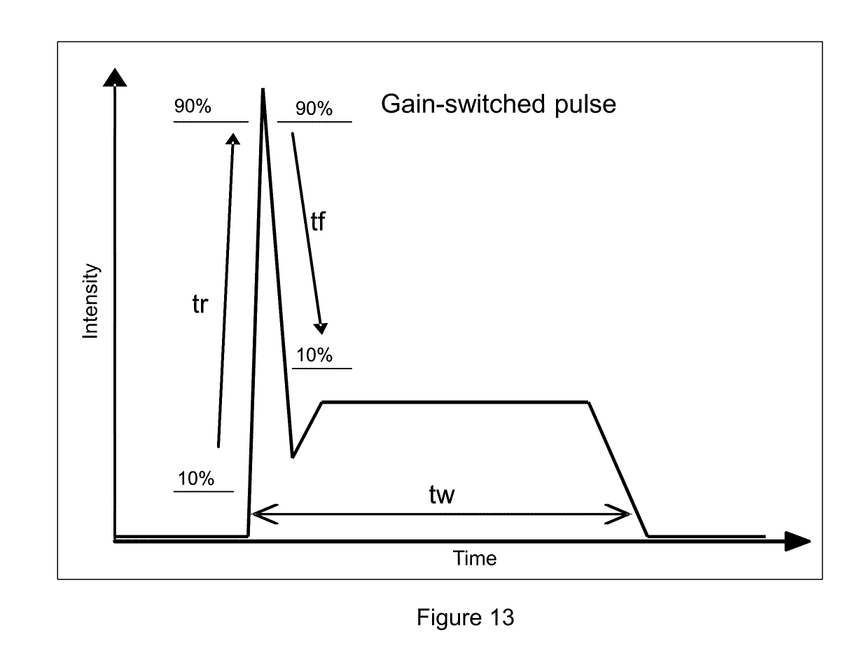

The linear polarization output characteristics is tested on a three reflector VCSEL device constructed with a polarization selective third reflector described earlier. FIG. 13 schematically represents general characteristics of a typical gain switched optical pulse from a two or three reflector VCSEL device. More specifically, the Time vs Intensity plot shows optical pulse during the fast rise time after a current pulse is applied. There is an initial rapid rising gain switching spike in optical intensity resulting from the relaxation oscillation and quickly damps out. After the initial spike the pulse intensity stabilizes to a constant value until the current pulse is turned off. In a VCSEL device having no built-in polarization control mechanism (for example, no or low level anisotropy such as elliptical aperture, strain in the gain region, etc.) the gain switching spike is unpolarized. As the pulse intensity stabilizes the output becomes increasingly polarized and for long pulses, QCW or CW operation, the output will typically be linearly polarized.

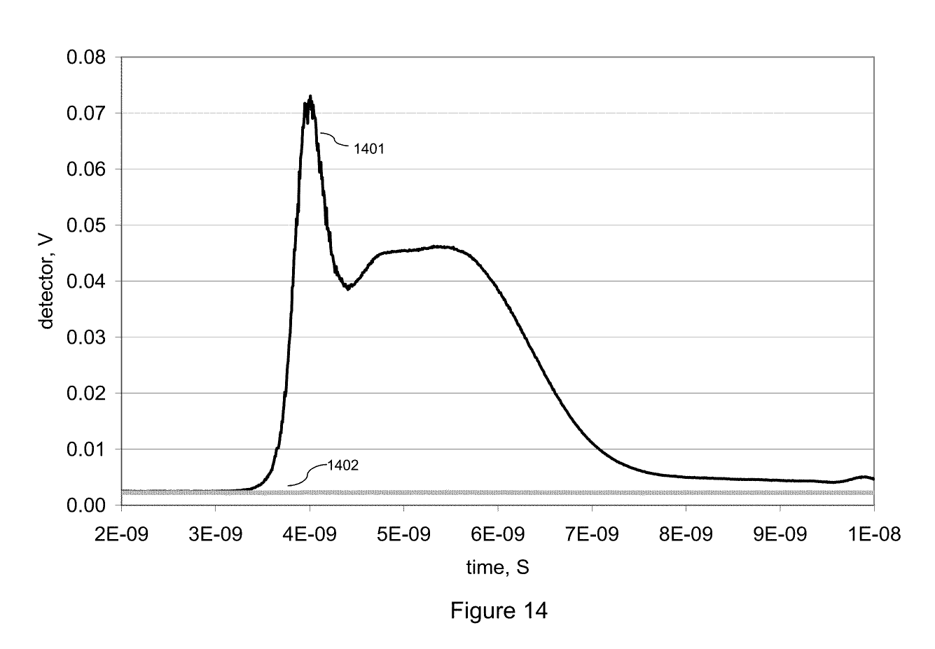

It is expected that a VCSEL device constructed with a strong built-in polarization selection mechanism would provide a linearly polarized output even in the fast rising end of the pulse. Polarization characteristics of a VCSEL device configured using a polarization selective third reflector described earlier is experimentally tested. FIG. 14 shows the output pulse response. The two traces on the plot 1401 and 1402 show time response of TE and TM polarization components of the VCSEL device laser pulse. The dominant optical pulse is TE polarized including in the fast rising gain switched regime. There is practically no residual TM polarization component including in the gain switched region.

### Polarization Controlled VCSEL Arrays:

The discussion so far is primarily on single VCSEL device for clarity. It is important to realize that the embodiments of the invention are also completely compatible with an array of VCSEL devices disposed on a chip configured using a polarization selective third reflector to obtain linearly polarized output. Since VCSELs are surface emitting they are suitable to be configured in two dimensional arrays in many different layouts. Furthermore, VCSELs in an array may be electrically connected for operating individually, in one or more small groups (sub-arrays) or collectively. Where the VCSELs are configured individually or in groups the individual VCSEL electrical contacts are routed to separate contacts on the chip for connecting to the relevant contacts on the submount or PCB. In a configuration where all VCSEL devices are operated collectively all the top and bottom contacts from individual VCSEL devices are connected together to a respective individual electrical bonding pad on a submount or a printed circuit board.

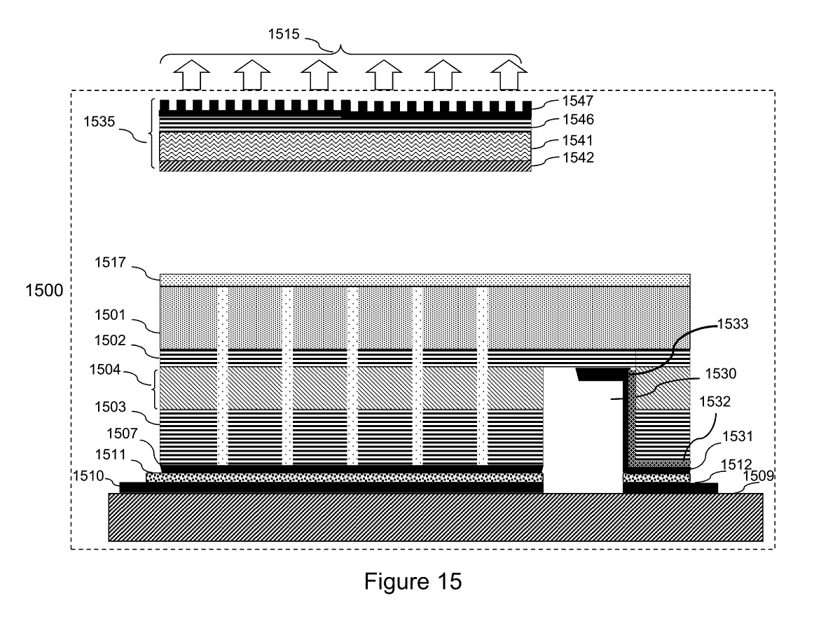

FIG. 15 shows a configuration where all the VCSEL devices in an array operable collectively. This configuration is selected only for illustrative purpose and does not preclude other modes of operation namely, individually addressable and groups and sub-arrays. The most practical approach to configure a VCSEL chip including an array of VCSEL devices in surface mountable form shown in FIG. 15. It should be understood that one goal of the invention is to construct VCSEL array on a chip compatible with high volume manufacturing and packaging methods.

The VCSEL device (an array in this context) is configured in a bottom emitting mode because that is most efficient for rapid heat dissipation from the chip. The basic structure is similar to bottom emitting VCSEL devices described earlier in reference with FIG. 3a for example, except that the description and underlying principles are now applied to a larger area chip. As a consequence, measures to correct for bow in the substrate (FIG. 7), is more important. More description of a process suitable for large area wafer is provided in the U.S. patent application Ser. No. 14/634,902 by Wang et al. filed on Mar. 2, 2015, co-authored by the inventors of this application and co-owned by Princeton Optronics Inc. Mercerville, N.J., also the Assignee of this application.

Referring now to FIG. 15, and in particular to the extended cavity VCSEL array 1500, the entire epitaxial layer sequence for the basic VCSEL device structure is grown on a large area (6″ diameter) substrate 1501. The basic elements comprise a bottom DBR 1502, a gain region 1504 and a top DBR 1503, respectively. The bottom and top DBR form an internal resonant cavity. The gain region is similar to the one described in FIG. 2, including several MQW groups separated by tunnel diodes to increase gain. The top contact 1507 is deposited on the top DBR. Electrical connection to the bottom DBR (or substrate) is made through a bottom contact 1533 in a trench 1530 and connected to a contact region 1531 coplanar with the top contact. It is noted that all the VCSEL devices are connected together to a common top contact (through the contiguous metal layer 1507), and a common bottom contact (through the contact 1533 to the bottom DBR 1502 or to the substrate 1501). A dielectric material 1532 is provided for preventing current flow directly into the region underneath the contact pad 1531. An antireflection coating 1517 is deposited on the bottom surface of the substrate. The basic structure is very similar to the single VCSEL device shown in FIG. 3a but applied to an array.

The entire array is surface mounted to contact pads 1510 (top contact) and 1512 (bottom contact) on a submount 1509. Electrical connection to the VCSEL array is provided through the contact pads on the submount. A third reflector including a polarization selective third reflector to set up the lasing cavity may be implemented in many different ways described earlier in reference with FIGS. 4 and 12. In this particular example an external polarization selective reflector is used to configure the lasing cavity. While the embodiment is shown to have a flat third reflector 1535 including a reflective coating 1546 and a grating 1547 deposited on one surface of a transparent substrate 1541, and an antireflection coating 1542 on the surface facing the substrate 1501 of the VCSEL array.

It can be appreciated that the process of constructing VCSEL array and in particular, the surface mountable VCSEL array with polarization selective third reflector in various forms, is compatible with high volume manufacturing processes. In practice the VCSEL array is constructed on a 6″ diameter semiconductor wafer. The polarization selective reflector is constructed separately on a 6″ diameter transparent substrate and bonded to the VCSEL array semiconductor wafer using a transparent bonding material. The entire three reflector polarization selective VCSEL device chip on a 6″ diameter wafer diameter may be tested using on-chip test methods. One advantage is that the performance may be evaluated before dicing and packaging. Individual VCSEL devices, arrays or sub-arrays are diced and bonded to submounts using surface mount processes that are compatible with high volume turn around.

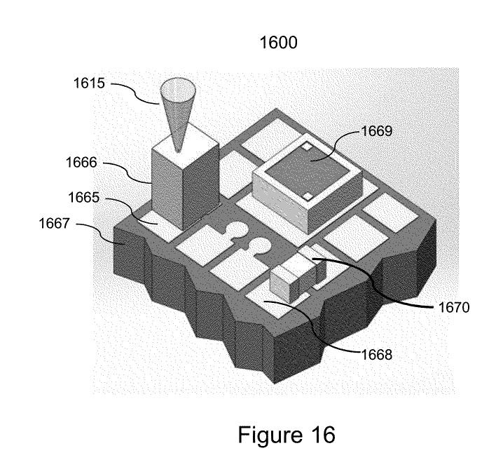

FIG. 16 shows a VCSEL module 1600 incorporating the principles of this invention and assembled in a high volume manufacturing process on a submount or a PCB 1667. The submount has an electronic circuit conductor pattern which may include one or more circuit layers. The top circuit layer including the electrically conducting pads (for example, 1668, 1665 etc.) is designed for bonding the VCSEL device 1666 and other electronics components on to respective bonding pads. The other components for example include driver ICs 1669 for providing driving current to the VCSEL device to produce laser output 1615, and other active and passive components 1670 to realize a functional optical module.

From the description provided in the previous sections, those skilled in the art eill be able to practice the principles of this invention and apply the concepts to a wide range of high brightness VCSEL device (including arrays), to achieve polarization selective operation. The various configurations make them very compatible with a wide range of module assembly processes. The modular and surface mount aspects of design are particularly attractive for reducing manufacturing cost by producing the modules in large volumes. Since VCSELs can be constructed using different materials, different wavelength emission devices may be combined together in a modular fashion to create a multi-wavelength module. These and other advantages of the principles disclosed here will be apparent to those skilled in the art.

Although a broad framework of the invention is described with reference to a few preferred embodiments, other embodiments may be configured by applying combinations and sub-combinations of elements described herein, depending on particular high brightness VCSEL application. Variations and modifications of different embodiments that will be apparent to those skilled in the art are within the scope of the invention and are covered by appended claims.

What is claimed is:

1. A VCSEL device comprising one or more VCSEL constructed on a common substrate, each VCSEL comprising:
a first and a second reflectors forming a cavity having periodic resonant optical modes exhibiting nodes and antinodes;
a gain region positioned between the first and second reflectors, said gain region including;
a plurality of gain segments in tandem, each gain segment located in physical space coinciding with a different one of an antinode of the periodic resonant optical modes, wherein each gain segment includes one or more quantum wells bounded by confinement regions, one on either side,
a tunnel junction positioned between adjacent gain segments, and
one or more current confining apertures located within the gain region in a position that is one selected from the group consisting of, between one or more of the gain segments, between the gain region and the first reflector, the gain region and the second reflector, and a suitable combination thereof, and
first and second electrical contact regions providing electrical connection to first and second electrical terminals of the VCSEL device, respectively; and
a third reflector placed at a distance away from the VCSEL device to set up an extended cavity to facilitate high power and high brightness laser emission.

2. The VCSEL device as in claim 1, wherein the first and second reflectors are one selected from a group consisting of a semiconductor Distributed Feedback Reflector, a multilayer dielectric reflector, and a metal reflector.

3. The VCSEL device as in claim 1, wherein the third reflector comprises a flat transparent substrate including a reflective coating on a first surface and a flat second opposing surface bonded to the VCSEL device.

4. The VCSEL device as in claim 3, wherein the opposing surface includes an optional antireflection coating between the opposing surface and the VCSEL device.

5. The VCSEL device as in claim 1, wherein the third reflector comprises a transparent substrate including a flat surface with a reflective coating, and an opposing curved surface with the curved surface positioned to face the VCSEL device, such that the third reflector functions as a curved reflector.

6. The VCSEL device as in claim 1, wherein the third reflector comprises a reflective coating deposited on the surface of the substrate that is opposite to the surface with the VCSEL device, such that the length of the laser cavity is extended by the thickness of the substrate.

7. The VCSEL device as in claim 1 further including a linear grating positioned proximal to the third reflector, wherein the grating periodicity is designed to impart high degree of polarization selectivity to the third reflector, such that lasing occurs only in a preferred linear polarization state.

8. The VCSEL device as in claim 7, wherein the linear grating is integrated with the third reflector.

9. The VCSEL device as in claim 7, wherein the third reflector comprises a multilayer coating on one surface of a transparent substrate, said multilayer coating including at least one reflective layer followed by a linear grating.

10. The VCSEL device as in claim 1, wherein the third reflector is positioned facing the second reflector, such that the extended laser cavity is set up between the first and third reflectors with the second reflector as the intermediate reflector.

11. The VCSEL device as in claim 10, wherein reflectivity of the third reflector is selected substantially lower than the reflectivity of the first reflector, thereby allowing laser emission out of the third reflector.

12. The VCSEL device as in claim 10, wherein reflectivity of the third reflector is selected substantially higher than the reflectivity of the first reflector, thereby allowing laser emission out of the first reflector.

13. The VCSEL device as in claim 1, wherein the third reflector is positioned facing the first reflector, such that the extended laser cavity is set up between the second and third reflectors with the first reflector as the intermediate reflector.

14. The VCSEL device as in claim 13, wherein reflectivity of the third reflector is selected substantially lower than the reflectivity of the second reflector, thereby allowing laser emission out of the third reflector.

15. The VCSEL device as in claim 13, wherein reflectivity of the third reflector is selected substantially higher than the reflectivity of the second reflector, thereby allowing laser emission out of the second reflector.

16. The VCSEL device as in claim 1, wherein the substrate thickness is greater than 500 μm, and preferably 500-800 μm to reduce bowing of the VCSEL device.

17. The VCSEL device as in claim 1, wherein the first and second electrical contact regions are coplanar with respective surfaces including the first and second reflectors.

18. The VCSEL device as in claim 1 including a plurality of VCSELs electrically connected to operate in a mode that is one selected from individually addressable, collectively as one or more group, and a combination thereof.

19. The VCSEL device as in claim 1, wherein the first and second electrical contact regions are coplanar on the surface including the second reflector, wherein the electrical isolation between the first and second electrical contact regions is provided using one or more trench etched through the first reflector and the gain region to the second reflector in a region away from the cavity having periodic resonant optical modes, so as to facilitate surface mounting of the VCSEL device.

20. The VCSEL device as in claim 1, wherein the substrate is removed partially or completely.
